(19) United States
(12) Patent Application Publication
(10) Pub. No.: US 2025/0295004 A1
(43) Pub. Date: Sep. 18, 2025

(54) DISPLAY DEVICE

(71) Applicant: Samsung Display Co., LTD., Yongin-si (KR)

(72) Inventor: Hyun Joon OH, Yongin-si (KR)

(73) Assignee: Samsung Display Co., LTD., Yongin-si (KR)

(21) Appl. No.: 18/829,991

(22) Filed: Sep. 10, 2024

(30) Foreign Application Priority Data
Mar. 13, 2024 (KR) 10-2024-0035290

(51) Int. Cl. H10K 59/80

(52) U.S. Cl. CPC H10K 59/873

(57) ABSTRACT

A display device may include a display panel including a display area and a non-display area around the display area; a shock-absorbing layer disposed on the display panel and disposed in the display area, and an anti-warpage layer disposed on the display panel and disposed in the non-display area and disposed at partially along an edge area of the shock-absorbing layer.

### CROSS-REFERENCE TO RELATED APPLICATION(S)

This application claims priority under 35 U.S.C. § 119 to and benefits of Korean Patent Application No. 10-2024-0035290 filed on Mar. 13, 2024 in the Korean Intellectual Property Office, the entire contents of which are incorporated herein by reference.

### BACKGROUND

### 1. Technical Field

The disclosure relates to a display device.

### 2. Description of the Related Art

As the information-oriented society evolves, various demands for display devices are ever increasing. For example, display devices are being employed in a variety of electronic devices such as smart phones, digital cameras, laptop computers, navigation devices, and smart televisions.

As such display devices, a variety of types of display devices such as liquid-crystal display (LCD) devices and organic light-emitting display (OLED) devices are currently being used. Among them, an organic light-emitting display device displays images by using an organic light-emitting element that emits light as electrons and holes recombine. Such an organic light-emitting display device includes multiple transistors for providing a driving current to the organic light-emitting element.

Recently, many approaches have been made to reduce the thickness of display devices in order to make them lighter.

Specifically, in order to reduce the weight and the thickness of display devices, the stacked structure of the internal elements may be eliminated, minimized, or replaced with a thinner substrate. As a result, the mechanical strength of the device may become weak. Since the mechanical strength of such a device becomes weak as the weight and thickness of the device decrease, warpage may occur in the device due to the influence of storage conditions, such as temperature and humidity. Such warpage may result in a curl in the device.

### SUMMARY

Aspects of the disclosure provide a display device that can prevent warpage of a display device without increasing the thickness and suppress a curl due to warpage.

According to an embodiment of the disclosure, a display device may include a display panel including a display area and a non-display area around the display area, a shock-absorbing layer disposed on the display panel and disposed in the display area; and an anti-warpage layer disposed on the display panel the anti-warpage layer may be disposed in the non-display area and may be disposed at least partially along an edge area of the shock-absorbing layer.

In an embodiment, the shock-absorbing layer has an upper surface being substantially flat.

In an embodiment, the anti-warpage layer an upper surface being substantially flat.

In an embodiment, the upper surface of the shock-absorbing layer and the upper surface of the anti-warpage layer may be coplanar with each other.

In an embodiment, the shock-absorbing layer may be a transparent resin layer, may have a same shape as the display area of the display panel, and may overlap the display area of the display panel.

In an embodiment, the shock-absorbing layer may include a lower surface facing an upper surface of the display panel, an upper surface opposite to the lower surface of the shock-absorbing layer, and a side surface disposed in a peripheral direction between the lower surface of the shock-absorbing layer and the upper surface of the shock-absorbing layer, and wherein the side surface of the shock-absorbing layer may be in contact with the anti-warpage layer in the peripheral direction.

In an embodiment, the display device may further include a soft layer disposed on at least one of the upper surface and the lower surface of the shock-absorbing layer, wherein the soft layer may have a lower strength than the shock-absorbing layer.

In an embodiment, the soft layer may include a first soft layer in contact with the upper surface of the shock-absorbing layer and a second soft layer in contact with the lower surface of the shock-absorbing layer.

In an embodiment, the second soft layer may be disposed between the lower surface of the shock-absorbing layer and the upper surface of the display panel, and wherein the second soft layer may have a lower strength than the first soft layer.

In an embodiment, the display device may further include a polarizing member in contact with the upper surface of the shock-absorbing layer, and a cover panel disposed on a lower surface of the display panel, wherein the lower surface of the display panel may be opposite to the upper surface of the display panel.

In an embodiment, the anti-warpage layer may have a rectangular frame, a circular shape, or oval shape including an empty space inside, and wherein the shock-absorbing layer may be accommodated in the empty space of the anti-warpage layer.

In an embodiment, the anti-warpage layer may have a same shape as the non-display area of the display panel and may overlap the non-display area.

In an embodiment, the anti-warpage layer may include a resin or metal having greater strength than the shock-absorbing layer.

In an embodiment, the anti-warpage layer may include at least one material selected from the group consisting of: aluminum (Al), carbon fiber-reinforced plastic (CFRP), and stainless steel (SUS304).

In an embodiment, the anti-warpage layer may include an inner side surface in contact with the side surface of the shock-absorbing layer in a peripheral direction, and an outer side surface disposed at an outermost position on an opposite side to the inner side surface of the anti-warpage layer, and wherein an outer side surface of the display panel at the outermost position and the outer side surface of the anti-warpage layer disposed on a same plane that extends in a vertical direction perpendicular to the upper surface of the display panel.

In an embodiment, the display device may further include a soft layer disposed on at least one of the upper surface and the lower surface of the shock-absorbing layer, the soft layer may have a lower strength than that of the shock-absorbing layer, wherein the anti-warpage layer may include an upper surface disposed above the inner side surface and the outer side surface of the anti-warpage layer, and a lower surface opposite to the upper surface of the anti-warpage layer, and wherein at least one of the inner side surface, the upper surface and the lower surface of the anti-warpage layer may be in contact with the soft layer.

According to an embodiment of the disclosure, a display device may include a display panel comprising a first area and a second area disposed adjacent to the first area, a resin layer disposed on the first area of the display panel and having a first strength, and a frame layer disposed on the second area of the display panel and having a second strength greater than the first strength.

In an embodiment, the second strength may be in a range of about 5 to about 50 times the first strength.

In an embodiment, the frame layer may include a metal frame with an empty space inside, and the metal frame may have a width in a range of about 1 mm to about 10 mm.

In an embodiment, the resin layer and the frame layer may be at least partially in contact with each other.

According to an embodiment of the disclosure, it may be possible to prevent warpage of a display device without increasing a thickness, it may also be possible to suppress formation of a curl due to warpage.

However, aspects of the disclosure are not restricted to the one set forth herein. The above and other aspects of the disclosure will become more apparent to one of ordinary skill in the art to which the disclosure pertains by referencing the detailed description of the disclosure given below.

### BRIEF DESCRIPTION OF THE DRAWINGS

The above and other aspects and features of the disclosure will become more apparent by describing in detail embodiments thereof with reference to the attached drawings, in which:

FIG. 1 is an exploded, perspective view of a display device according to an embodiment of the disclosure.

FIG. 2 is a plan view showing the display panel of FIG. 1.

FIG. 3 is a schematic cross-sectional view showing the structure of the display panel of FIG. 2.

FIG. 4 is an enlarged schematic cross-sectional view of a stack structure of the display panel of FIG. 3.

FIG. 5 is a schematic cross-sectional view of the display device of FIG. 1 in case that it is assembled.

FIG. 6 is a schematic cross-sectional view taken along line X-X of FIG. 5.

FIG. 7 is a plan view of the display device of FIG. 5.

FIG. 8 is a schematic cross-sectional view of a display device according to an embodiment of the disclosure.

FIGS. 9 to 34 are schematic cross-sectional views of display devices according to other embodiments of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc., (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc., may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scope of the inventive concepts. Further, the blocks, parts, and/or modules of some embodiments may be physically combined into more complex blocks, parts, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure will be described with reference to the accompanying drawings.

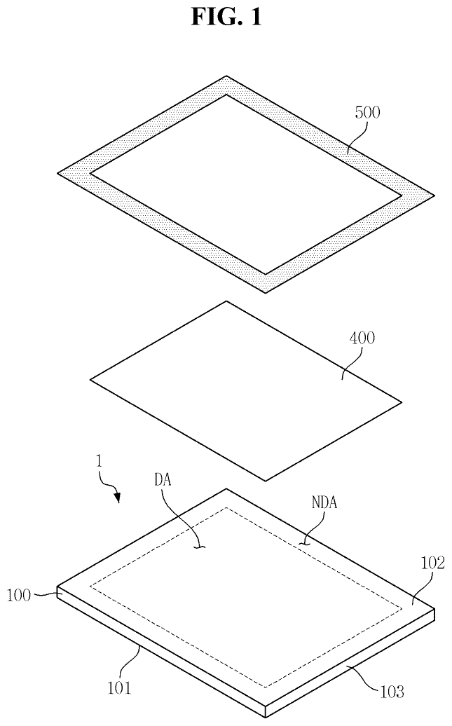

FIG. 1 is an exploded, perspective view of a display device according to an embodiment of the disclosure.

A display device 1 may refer to any electronic device that provides a display screen. The display device 1 may include devices for providing a display screen, such as a mobile phone, a smart phone, a tablet personal computer (PC), an electronic watch, a smart watch, a watch phone, a mobile communications terminal, an electronic notebook, an electronic book, a portable multimedia player (PMP), a navigation device, a game machine, a digital camera, a television set, a laptop computer, a netbook, a monitor, an electronic billboard, etc.

Referring to FIG. 1, the display device 1 may include a display panel 100, a shock-absorbing layer 400 disposed on the display panel 100, and an anti-warpage layer 500 disposed at the periphery of the shock-absorbing layer 400.

The display panel 100 may include an upper surface 102 of the display panel 100 facing the shock-absorbing layer 400 and the anti-warpage layer 500, a lower surface 101 of the display panel 100 opposite to the upper surface 102, and a side surface 103 of the display panel 100 disposed between the upper surface 102 and the lower surface 101 and disposed at the outermost position of the peripheral surface of the display panel.

The upper surface 102 may be a screen on which images are displayed, and the lower surface 101 may be opposite to the upper surface 102. According to the embodiment of the disclosure, the display panel 100 may be a top-emission display panel that displays images only on the upper surface 102. Although the top-emission display panel will be described as the display panel 100 in the following descriptions, it may be to be understood that the disclosure is not limited thereto. For example, the display panel 100 may be a bottom-emission display panel that displays images on the lower surface 101, or may be a dual-emission display panel that displays images on both the upper surface 102 and the lower surface 101 of the display panel.

The shock-absorbing layer 400 may be disposed on the upper surface 102 of the display panel. The shock-absorbing layer 400 may prevent external shocks from being transmitted to the display panel 100 or may disperse internal shocks. The shock-absorbing layer 400 may overlap the display screen corresponding to a display area DA of the display panel 100, which will be described later, and may be transparent so as not to block the display screen.

The anti-warpage layer 500 may be disposed around the shock-absorbing layer 400. The anti-warpage layer 500 may share a plane with the shock-absorbing layer 400. For example, the anti-warpage layer 500 and the shock-absorbing layer 400 may constitute a same layer. In other words, the shock-absorbing layer 400 and the anti-warpage layer 500 may be disposed in a same layer. For example, the anti-warpage layer 500 may be disposed on the upper surface 102 of the display panel like the shock-absorbing layer 400.

The anti-warpage layer 500 may at least partially surround the shock-absorbing layer 400 when viewed from the top (or a plan view). While the anti-warpage layer 500 overlaps the display panel 100 in the thickness direction, it may overlap the non-display area NDA but not the display area DA of the display panel 100, which will be described later. There may be a variety of modifications. Various positional relationships of the anti-warpage layer 500 will be described later.

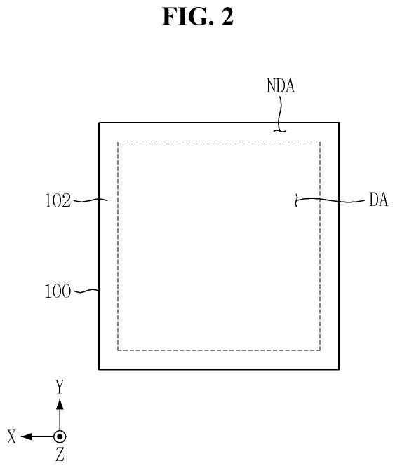

FIG. 2 is a plan view showing the display panel of FIG. 1.

Referring to FIG. 2, the display panel 100 may have a rectangular shape when viewed from the top. It should be understood, however, that the embodiments of the disclosure are not limited thereto. The display panel 100 may have a variety of shapes depending on the applications, such as a square, a diamond, other polygons, a circle, and an oval.

The display panel 100 may be divided into a display area DA and a non-display area NDA depending on whether an image may be displayed or not. The non-display area NDA may be disposed around the display area DA, and the non-display area NDA may surround the display area DA at least partially or entirely.

The display panel 100 may include one or more light sources that provide light. For example, the display panel may be a light-receiving panel including an external light source, or a self-luminous panel including an internal light-emitting element. A self-luminous panel includes multiple light-emitting elements. Examples of the light-emitting elements may include an organic light-emitting diode, a quantum-dot light-emitting diode, an inorganic-based micro light-emitting diode (e.g., Micro LED), an inorganic-based nano light-emitting diode (e.g., nano LED), etc. In the following description, an organic light-emitting diode may be employed as the light-emitting element for convenience of illustration. It should be understood, however, that the embodiments of the disclosure are not limited thereto.

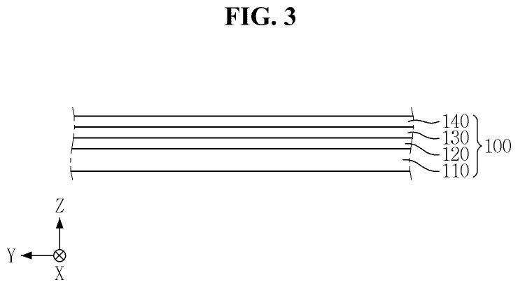

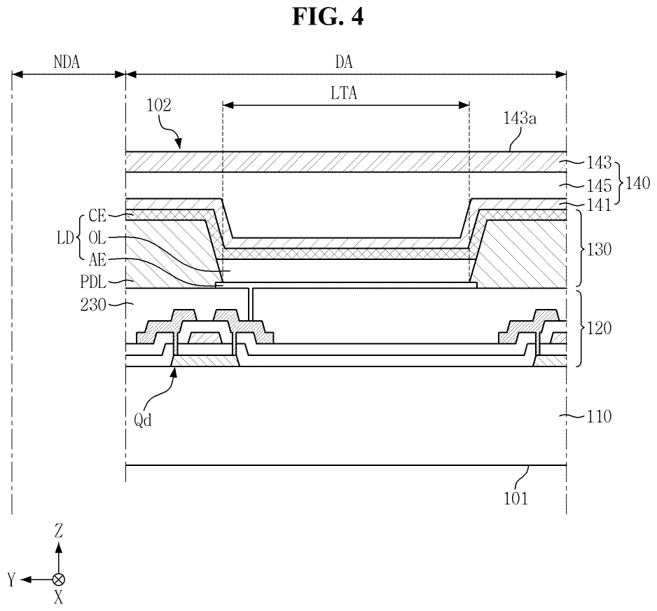

FIG. 3 is a schematic cross-sectional view schematically showing the structure of the display panel of FIG. 2. FIG. 4 is an enlarged schematic cross-sectional view of a stack structure of the display panel of FIG. 3.

Referring to FIG. 3, the display panel 100 may include a base substrate 110, a driving layer 120, a light-emitting element layer 130, and an encapsulation layer 140.

Referring to FIG. 4, the base substrate 110 may provide space for the driving layer 120, the light-emitting element layer 130, and the encapsulation layer 140. The base substrate 110 may be a flexible substrate and may be made of a flexible polymer material. For example, the base substrate 110 may be made of a flexible plastic such as polyimide, polyethylene ether phthalate, polyethylene naphthalate, polycarbonate, polyarylate, polyetherimide, polyether sulfone, or a combination thereof. As an example, the base substrate 110 may be a rigid substrate such as glass, a semiconductor substrate, a quartz substrate, or a combination thereof.

The driving layer 120 includes elements for providing signals to the light-emitting element layer 130. The driving layer 120 may include a variety of signal lines, e.g., a scan line (not shown), a data line (not shown), a power line (not shown), and an emission line (not shown). The driving layer 120 may include multiple transistors and multiple capacitors. The transistors may include a switching transistor (not shown) and a driving transistor Qd provided for each pixel (not shown).

The light-emitting element layer 130 may include a light-emitting element LD, and the light-emitting element LD may include a first electrode AE, an organic layer OL, and a second electrode CE.

The light-emitting element layer 130 may further include a pixel-defining layer PDL disposed on the protective film 230. The pixel-defining layer PDL may include an opening exposing the first electrode AE and define a light-emitting area LTA when viewed from the top.

The encapsulation layer 140 may be disposed on the light-emitting element layer 130. The encapsulation layer 140 can block the light-emitting element layer 130 from outside moisture and oxygen.

The encapsulation layer 140 may be a thin-film encapsulation layer and may include one or more organic films and one or more inorganic films. For example, the encapsulation layer 140 may include a first inorganic film 141 disposed on the second electrode CE, an organic film 145 disposed on the first inorganic film 141, and a second inorganic film 143 disposed on the organic film 145.

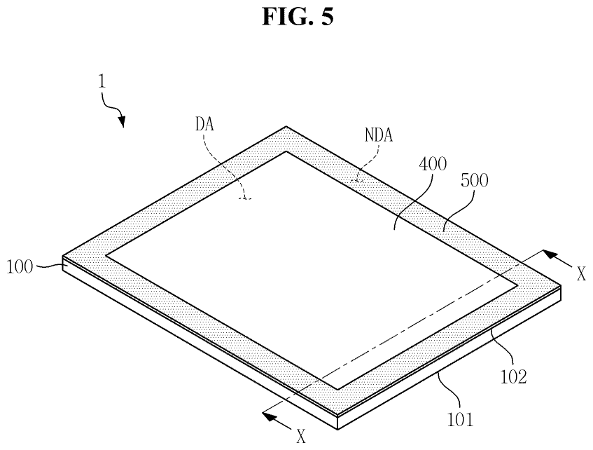

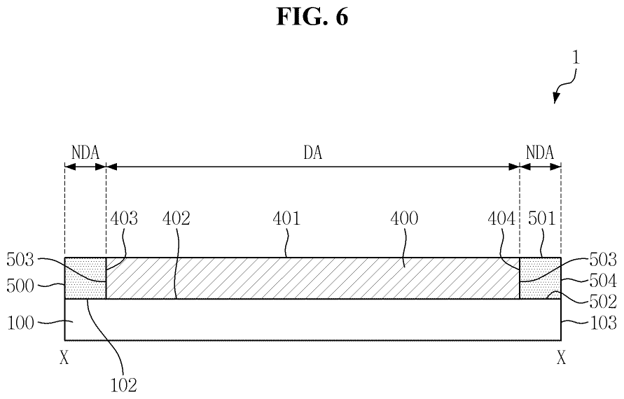

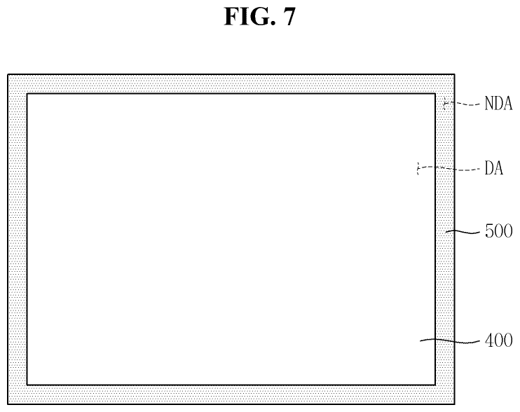

FIG. 5 is a schematic cross-sectional view of the display device of FIG. 1 in case that it is assembled. FIG. 6 is a schematic cross-sectional view taken along line X-X of FIG. 5. FIG. 7 is a plan view of the display device of FIG. 5.

Referring to FIGS. 4 and 5, the shock-absorbing layer 400 may be disposed on the upper surface 102. According to an embodiment of the disclosure, the shock-absorbing layer 400 may be disposed on (e.g., directly on) the upper surface 102. Specifically, the lower surface of the shock-absorbing layer 400 and the upper surface 102 of the display panel may be in contact (e.g., direct contact) with each other. The layer or material in contact (e.g., direct contact) with the lower surface of the shock-absorbing layer 400 may be associated with the layer or material forming the upper surface 102 (i.e., the top surface) of the display panel 100. For example, if the top surface of the display panel 100 is the upper surface of the encapsulation layer 140, i.e., an upper surface 143a of the second inorganic film 143 as shown in FIG. 4, the shock-absorbing layer 400 may be disposed on (e.g., directly on) the upper surface of the second inorganic film 143 of the encapsulation layer 140. It is, however, to be understood that the disclosure is not limited thereto. A separate layer may be disposed between the lower surface of the shock-absorbing layer 400 and the upper surface 102 of the display panel.

Referring to FIG. 6, the area of the lower surface of the shock-absorbing layer 400 in contact with the upper surface 102 of the display panel may be the entirety or a part of the lower surface 402 of the shock-absorbing layer of FIG. 6, which will be described later. Specifically, the lower surface 402 of the shock-absorbing layer may be in contact with a part of the upper surface 102 of the display panel, or the entire lower surface 402 of the shock-absorbing layer may be in contact with the upper surface 102 of the display panel.

In some embodiments, the shock-absorbing layer 400 may overlap the display area DA of the display panel 100 in the thickness direction of the display panel 100. Specifically, the shock-absorbing layer 400 may overlap the display area DA of the display panel 100 in a direction perpendicular to the upper surface 102 of the display panel in the schematic cross-sectional view of FIG. 6.

In case that an external shock is applied to the display area DA of the display panel 100, the shock-absorbing layer 400 can absorb the external shock at a position overlapping the display area DA to prevent the shock from being transmitted to the display area DA, thereby protecting the display area DA. In other words, the shock-absorbing layer 400 can have shock resistance characteristics.

In the schematic cross-sectional view of FIG. 6, the shock-absorbing layer 400 may include a lower surface 402 of the shock-absorbing layer facing the upper surface 102 of the display panel, an upper surface 401 opposite to the lower surface 402, and side surfaces 403 and 404 disposed between the lower surface 402 and the upper surface 401 and facing the anti-warpage layer 500.

The side surfaces 403 and 404 of the shock-absorbing layer may include a first side surface 403 and a second side surface 404 facing on the opposite side from the first side surface 403.

The first and second side surfaces 403 and 404 of the shock-absorbing layer may form four peripheral surfaces facing the anti-warpage layer 500 in the peripheral direction of the shock-absorbing layer. If the shock-absorbing layer 400 has a rectangular shape, it may include four side surfaces 403 and 404, but the disclosure is not limited thereto. In case that the shock-absorbing layer 400 is circular, the side surfaces 403 and 404 may include a peripheral surface. In case that the shock-absorbing layer 400 is polygonal, it may include as many side surfaces as the number of faces of the polygon.

Although a pair of side surfaces 403 and 404 among the four side surfaces of the shock-absorbing layer have the same shape in the schematic cross-sectional view of FIG. 6, the disclosure is not limited thereto. All of the four side surfaces 403 and 404 may have the same shape, or at least one of the four side surfaces 403 and 404 may have a different shape.

The first side surfaces 403 may be in contact (e.g., direct contact) with the inner side surfaces 503 of the anti-warpage layer, which will be described later, at the boundary between the display area DA and the non-display area NDA. For example, a separate layer may be disposed between each first side surface 403 of the shock-absorbing layer and a corresponding inner side surface 503 of the anti-warpage layer.

As such, the first side surfaces 403 of the shock-absorbing layer 400 may be in contact (e.g., direct contact) with the inner side surfaces 503 of the anti-warpage layer, or may be in indirect contact with a separate layer disposed between. A gap may be formed between the first side surfaces 403 of the shock-absorbing layer 400 and the inner side surfaces 503 of the anti-warpage layer 500 so that the first side surfaces 403 of the shock-absorbing layer 400 may not be in contact (e.g., direct contact) with the inner side surfaces 503 of the anti-warpage layer 500. In the schematic cross-sectional view of FIG. 6, a pair of gaps may be disposed between a pair of first side surfaces 403 and of the shock-absorbing layer and a pair of inner side surfaces 503 of the anti-warpage layer, or a gap may be disposed between a first side surface 403 of the shock-absorbing layer and an inner side surface 503 of the anti-warpage layer.

At least one first side surface 403 of the shock-absorbing layer may be in contact with an inner side surface 503 of the anti-warpage layer. For example, the first side surface 403 of the shock-absorbing layer may be partially in contact with the inner side surface 503 of the anti-warpage layer, or the entire surface of the first side surface 403 of shock-absorbing layer may be in contact with the inner side surface 503 of the anti-warpage layer.

The height of the upper surface 401 of the shock-absorbing layer in the thickness direction of the display panel 100 may be equal to the height of the anti-warpage layer 500, but the disclosure is not limited thereto. The height of the upper surface 401 of the shock-absorbing layer may be smaller or greater than the height of the anti-warpage layer 500.

The upper surface 401 of the shock-absorbing layer may be a substantially flat, a straight line shape or have a curved line shape, or may have an irregular surface roughness.

Referring to FIG. 7, the shock-absorbing layer 400 may have an area smaller than the overall area of the display panel 100, for example, may have the same shape and area as the display area DA to cover the display area DA at the central area of the display panel 100.

The shock-absorbing layer 400 may have a rectangular shape conforming to the shape of the display area DA of the display panel 100, but the disclosure is not limited thereto. Depending on the shape of the display panel 100, the shock-absorbing layer 400 may be modified in a variety of ways.

The shock-absorbing layer 400 may be made of any material as long as it may be a transparent material that provides shock resistance and transmits light. For example, a layer with additional functions other than shock absorption may be referred to as the shock-absorbing layer 400 as long as it provides shock resistance and includes a transparent material that can transmit light. Examples of the shock-absorbing layer 400 may include a window film, a window resin, an optical adhesive resin, an optical adhesive film, a functional electronic film, an optical film, a combination thereof, etc. Examples of the functional electronic film may include a touch film, a fingerprint sensing film, etc. Examples of the optical film may include a polarizing film, an anti-reflection film, an anti-fingerprint film, a viewing angle control film, a combination thereof, etc. The films, layers, etc. may form the shock-absorbing layer alone, or two or more films or layers may be stacked on each other to form the shock-absorbing layer 400.

According to an embodiment of the disclosure, the shock-absorbing layer 400 may include a photo-curable or thermo-curable resin. For example, the shock-absorbing layer may include at least one of polyester acrylate, epoxy acrylate, urethane acrylate, polyether acrylate, silicone acrylate, alicyclic epoxy resin, glycidyl ether epoxy resin, epoxy acrylate and vinyl ether.

The shock-absorbing layer 400 may be formed by preparing the anti-warpage layer 500 in the form of a frame, placing the anti-warpage layer 500 on the display panel 100, and then filling the inside of the frame with a filling liquid for the shock-absorbing layer using slit coating, dispensing, or ink jetting technique. It should be understood, however, that the embodiments of the disclosure are not limited thereto. The shock-absorbing layer 400 may be formed as a film and accommodated inside the anti-warpage layer 500.

The modulus (or Young's modulus) of the shock-absorbing layer 400 may be, for example, in a range of about 0.1 MPa to about 50 GPa, preferably in a range of about 1 GPa to about 10 GPa. It should be understood, however, that the embodiments of the disclosure are not limited thereto.

The shock-absorbing layer 400 may have a thickness in a range of about 10 μm to about 1000 μm, preferably a thickness in a range of about 50 to about 300 μm. It should be understood, however, that the embodiments of the disclosure are not limited thereto.

If the thickness of the shock-absorbing layer 400 is equal to or greater than about 50 μm, the overall thickness of the device can be reduced. If the thickness of the shock-absorbing layer 400 is equal to or less than about 300 μm, the strength of the device can be reinforced and impact resistance can be improved.

Incidentally, referring to FIGS. 4 and 5, the anti-warpage layer 500 may be disposed on the upper surface 102 of the display panel. According to the embodiment, the anti-warpage layer 500 may be disposed on (e.g., directly on) the upper surface 102 of the display panel. Specifically, the lower surface of the anti-warpage layer 500 and the upper surface 102 of the display panel may be in contact (e.g., direct contact) with each other.

The layer or material in contact (e.g., direct contact) with the lower surface of the anti-warpage layer 500 may be associated with the layer or material forming the upper surface 102 (i.e., the top surface) of the display panel 100. For example, if the top surface of the display panel 100 is the upper surface of the encapsulation layer 140, i.e., an upper surface 143a of the second inorganic film 143 as shown in FIG. 4, the anti-warpage layer 500 may be disposed on (e.g., directly on) the upper surface of the second inorganic film 143 of the encapsulation layer 140. It is, however, to be understood that the disclosure is not limited thereto. A separate layer may be disposed between the lower surface of the anti-warpage layer 500 and the upper surface 102 of the display panel.

Referring to FIG. 6, the area of the lower surface of the anti-warpage layer 500 in contact with the upper surface 102 of the display panel may be the entirety or a part of the lower surface 502 of the anti-warpage layer 500, which will be described later. Specifically, the lower surface 502 of the anti-warpage layer 500 may be in contact with a part of the upper surface 102 of the display panel, or the entire lower surface 502 of the anti-warpage layer 500 may be in contact with the upper surface 102 of the display panel.

In some embodiments, the anti-warpage layer 500 may overlap the non-display area NDA of the display panel 100 in the thickness direction of the display panel 100. Specifically, the anti-warpage layer 500 may overlap the non-display area NDA of the display panel 100 in a direction perpendicular to the upper surface 102 of the display panel in the schematic cross-sectional view of FIG. 6.

The anti-warpage layer 500 has a high-strength rectangular frame shape with an empty space inside, and may be disposed along the side surfaces 403 and 404 of the shock-absorbing layer, which are the peripheral surfaces of the shock-absorbing layer 400. It can prevent warpage of the device at the perimeter of the shock-absorbing layer 400 and suppress a curl from occurring due to warpage, i.e., deformation such as distortion.

In the schematic cross-sectional view of FIG. 6, the anti-warpage layer 500 may include a lower surface 502 of the anti-warpage layer facing the upper surface 102 of the display panel, an upper surface 501 opposite to the lower surface 502, and side surfaces 503 and 504 disposed between the lower surface 502 and the upper surface 501 and facing the first side surface 403 of the shock-absorbing layer.

The side surfaces 503 and 504 of the anti-warpage layer may include an inner side surface 503 disposed at the boundary between the display area DA and the non-display area NDA and facing the first side surface 403 of the shock-absorbing layer, and an outer side surface 504 facing outward on the opposite side to the inner side surface 503.

The inner side surface 503 of the anti-warpage layer may be perpendicular to the lower surface 502 of the anti-warpage layer or may be inclined with respect to the lower surface 502 of the anti-warpage layer in the schematic cross-sectional view of FIG. 6.

If the inner side surface 503 of the anti-warpage layer is disposed at the boundary between the display area DA and the non-display area NDA, the anti-warpage layer 500 may overlap the non-display area NDA as shown in FIGS. 6 and 7. It should be understood, however, that the embodiments of the disclosure are not limited thereto. The inner side surface 503 of the anti-warpage layer may be disposed in the display area DA or may be disposed in the non-display area NDA.

The outer side surface 504 of the anti-warpage layer may be perpendicular to the lower surface 502 of the anti-warpage layer, or may be inclined the same direction as or the opposite direction to the inner side surface 503 of the anti-warpage layer in the schematic cross-sectional view of FIG. 6.

Based on a vertical connection line connecting the outer side surface 504 of the anti-warpage layer and the side surface 103 of the display panel in the thickness direction of the display panel 100, if the outer side surface 504 of the anti-warpage layer and the side surface 103 of the display panel are coplanar with each other as shown in FIG. 6, the anti-warpage layer 500 may overlap the non-display area NDA as shown in FIG. 7. It should be understood, however, that the embodiments of the disclosure are not limited thereto. The outer side surface 504 of the anti-warpage layer may extend beyond the vertical connection line and a part of the anti-warpage layer 500 may protrude outward from the side surface 103 of the display panel.

As such, the outer side surface 504 of the anti-warpage layer and the side surface 103 of the display panel in the non-display area NDA may be coplanar with each other, but the disclosure is not limited thereto. The inner side surface 503 of the anti-warpage layer may be disposed at the boundary between the display area DA and the non-display area NDA, or may be disposed in the display area DA.

The upper surface 501 of the anti-warpage layer may be substantially flat, have a straight line shape or a curved line shape, or may have an irregular surface roughness.

Based on a horizontal connection line connecting the upper surface 501 of the anti-warpage layer with the upper surface 401 of the shock-absorbing layer in a horizontal direction with respect to the vertical connection line, the upper surface 501 of the anti-warpage layer and the upper surface 401 of the shock-absorbing layer may be coplanar with each other as shown in FIG. 6, and the upper surface 501 of the anti-warpage layer and the upper surface 401 of the shock-absorbing layer may together form a substantially flat surface. It should be understood, however, that the embodiments of the disclosure are not limited thereto. The upper surface 501 of the anti-warpage layer may be disposed lower or higher than the horizontal connection line so that there may be a level difference between the upper surface 501 of the anti-warpage layer and the upper surface 401 of the shock-absorbing layer.

The lower surface 502 of the anti-warpage layer may be disposed on the upper surface 102 of the display panel. For example, like the shock-absorbing layer 400, it may be disposed on (e.g., directly on) the upper surface 102 of the display panel, but the disclosure is not limited thereto. A separate layer may be disposed between the upper surface 102 of the display panel and at least one of the lower surface 502 of the anti-warpage layer and the lower surface 402 of the shock-absorbing layer.

Referring to FIG. 7, the anti-warpage layer 500 may have the same shape as the non-display area NDA, may have the same area as the non-display area NDA, and may cover the non-display area NDA at the periphery of the display panel 100.

As the anti-warpage layer 500 may overlap the non-display area NDA, it may be possible to prevent warpage of the device without affecting the display pixels, i.e., without interfering with an image display path through which images may be seen to users.

The anti-warpage layer 500 may have a rectangular frame shape conforming to the shape of the non-display area NDA of the display panel 100, but the disclosure is not limited thereto. Depending on the shape of the display panel 100, the anti-warpage layer 500 may be modified in a variety of ways.

The anti-warpage layer may have a rectangular cross-sectional shape in the schematic cross-section of FIG. 6, or may have a polygonal cross-sectional shape other than a rectangular shape or a semicircular cross-sectional shape.

Referring to FIG. 7, the anti-warpage layer 500 may have a rectangular frame shape with an empty space in the middle. The shock-absorbing layer 400 may be accommodated in the empty space. The space inside the anti-warpage layer 500 may have a size equal to the size of the shock-absorbing layer 400 to accommodate the shock-absorbing layer 400.

The anti-warpage layer 500 may be disposed around the shock-absorbing layer 400 with the shock-absorbing layer 400 accommodated therein, and the anti-warpage layer 500 may surround the shock-absorbing layer 400. For example, the anti-warpage layer 500 may be disposed at the periphery of the shock-absorbing layer 400 while being in contact with the first side surfaces 403 of the shock-absorbing layer 400.

The anti-warpage layer 500 may be a high-strength frame with such a strength that it can prevent warpage and suppress curling. The anti-warpage layer 500 may include a black pigment in plastic resin or use metal to prevent light leakage and light reflection.

The anti-warpage layer 500 may be made of any material as long as it has higher strength than the shock-absorbing layer 400 and does not transmit light.

The anti-warpage layer 500 may have greater strength than the shock-absorbing layer 400, and the modulus of the anti-warpage layer 500 may be greater than that of the shock-absorbing layer 400. For example, it may be desirable that the modulus of the anti-warpage layer 500 may be in a range of about 5 to about 50 times greater than the modulus of the shock-absorbing layer 400. It should be understood, however, that the embodiments of the disclosure are not limited thereto.

The anti-warpage layer 500 may have a modulus in a range of about 50 GPa to about 200 GPa. It should be understood, however, that the embodiments of the disclosure are not limited thereto.

If the modulus of the anti-warpage layer 500 is about 50 GPa or more, in case that warpage occurs, for example, in case that deformation such as distortion occurs, the mechanical strength of the device can be reinforced in the non-display area NDA, which is the peripheral area of the display panel 100, to hold the non-display area NDA so that it may not be distorted.

If the modulus of the anti-warpage layer 500 is about 200 GPa or less, the high-strength material can hold the device strongly in the non-display area NDA, which is the peripheral area of the display panel 100 so that it may be possible to strongly suppress warpage of the device. The larger the modulus value is, the stronger the supporting force is, and thus deformation can be suppressed more effectively.

For example, the anti-warpage layer 500 may include at least one material selected from the group consisting of aluminum (Al), carbon fiber-reinforced plastic (CFRP), and stainless steel (SUS304).

Aluminum (Al) may have a modulus of about 69 GPa or more, carbon fiber-reinforced plastic (CFRP) may have a modulus of about 75 GPa, titanium (Ti) may have a modulus of about 116 GPa, and stainless steel (SUS304) may have a modulus of about 190 GPa.

The anti-warpage layer 500 may have a width in a range of about 1 mm to about 10 mm, preferably in a range of about 1 mm to about 3 mm or less, but the disclosure is not limited thereto.

With the width of the anti-warpage layer 500 equal to or greater than about 1 mm, the anti-warpage layer 500 can have a small width, thereby reducing the material cost for the anti-warpage layer 500. With the width equal to or less than about 10 mm, it may be possible to reliably prevent a curl. The larger the width is, the more reliably a curl can be prevented.

The anti-warpage layer 500 may have the same width along the peripheral direction, but the disclosure is not limited thereto. In the plan view of FIG. 7, for the anti-warpage layer consisting of four sides including a pair of shorter sides and a pair of longer sides, the width of the anti-warpage layer 500 may be different on at least one of the four sides.

The anti-warpage layer 500 having such a configuration may overlap the non-display area NDA with the shock-absorbing layer accommodated in the empty space inside, i.e., in contact with the second side surface 404 of the shock-absorbing layer in the peripheral direction to support the periphery of the shock-absorbing layer 400 as shown in FIGS. 6 and 7. Accordingly, in case that an external shock is applied to the device, the anti-warpage layer 500 can firmly support the position of the shock-absorbing layer 400 at the periphery of the shock-absorbing layer 400 so that the shock-absorbing layer 400 may not be displaced by the external shock and can absorb the external shock to protect the device. Specifically, the anti-warpage layer 500 can firmly support the position of the shock-absorbing layer so that the shock-absorbing layer 400 overlaps the display area DA and can absorb external shock to prevent external shock from being transmitted to especially the display area DA.

As the anti-warpage layer 500 may be disposed to overlap the non-display area NDA while accommodating the shock-absorbing layer 400 in the empty space inside, in case that the display device is to be distorted due to an external shock or the storage temperature, specifically, in case that force is concentrated on the center of the display area DA of the display panel 100, the high-strength anti-warpage layer 500 can hold, support and press the display panel 100 in the non-display area NDA corresponding to the outer peripheral area of the display panel 100 so that it may be possible to suppress warpage such as distortion of the device. In case that a curl is about to occur due to warpage, the anti-warpage layer 500 disposed at the outer perimeter of the display panel 100 can distribute the force that causes the warpage to occur at the outer perimeter of the display panel 100, thereby preventing a curl. As the anti-warpage layer 500 is disposed in the non-display area NDA corresponding to the outer periphery of the display panel 100 as described above, in case that warpage occurs and the force is centered, the high-strength anti-warpage layer 500 can hold on at the periphery to prevent the device from curling up to the center.

Hereinafter, other embodiments of the disclosure will be described.

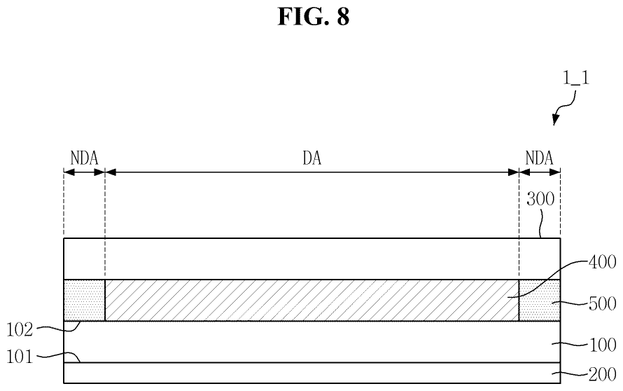

FIG. 8 is a schematic cross-sectional view of a display device according to an embodiment of the disclosure.

FIG. 8 shows an example where another layer or member may be added to the top and/or bottom of the display device of FIG. 6.

The embodiment of FIG. 8 may be different from the embodiment of FIG. 6 in that a display device 1_1 further includes a polarizing member 300 disposed above a display panel 100, and a cover panel 200 disposed on the lower surface 101 of the display panel 100.

Specifically, the cover panel 200 may be disposed on the lower surface 101 of the display panel and can protect the display panel 100 from below.

The cover panel 200 may include a buffer protection layer for absorbing shock, and a metal layer for dissipating heat and blocking electromagnetic waves.

Although the cover panel 200 may be made up of two layers including both the buffer protection layer and the metal layer, it may be made up of only one layer selected from the buffer protection layer and the metal layer.

The polarizing member 300 may be implemented as a polarizing plate that transmits only light vibrating in the same direction as the pattern while absorbing the light vibrating in another directions. The polarizing member may be disposed on the shock-absorbing layer 400 and the anti-warpage layer 500, and may express true black to increase the contrast ratio, reduce reflection of external light, or control the transmittance.

The polarizing member 300 may further include at least one functional layer among a hard coating layer, an anti-reflection (AR) coating layer, and an anti-glare (AG) coating layer.

The shock-absorbing layer 400 may be disposed between the lower surface of the polarizing member 300 and the upper surface 102 of the display panel in the display area.

The anti-warpage layer 500 may be disposed in the non-display area NDA, may be disposed at the periphery of the shock-absorbing layer 400, may be coplanar with each other, and may be disposed between the lower surface of the polarizing member 300 and the upper surface 102 of the display panel.

Even in this embodiment, since the polarizing member 300 may be disposed on the shock-absorbing layer 400 and the anti-warpage layer 500, in case that warpage occurs in the device, for example, the anti-warpage layer 500 under the polarizing member 300 can suppress the occurrence of a curl in the polarizing member due to the warpage. As a result, it may be possible to suppress a curl from occurring in the polarizing member 300 due to the warpage.

According to this embodiment, the cover panel 200 may be further disposed on the lower surface 101 of the display panel so that it may be possible to protect the display panel 100 from external shock from below the display panel 100.

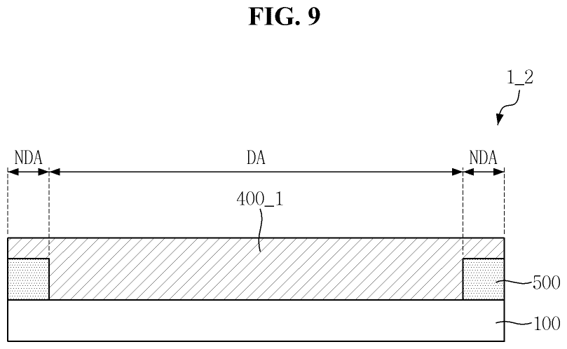

FIG. 9 is a schematic cross-sectional view of a display device according to an embodiment of the disclosure.

FIG. 9 shows a modification of the shape of a shock-absorbing layer 400_1. The embodiment of FIG. 9 is different from the embodiment of FIG. 5 in that the shock-absorbing layer 400_1 covers the upper surface of an anti-warpage layer 500 in a display device 1_2.

Specifically, a part of the shock-absorbing layer 400_1 in FIG. 9 may be accommodated in the anti-warpage layer 500, and the remaining part of the shock-absorbing layer 400_1 extended from it may cover the upper surface of the anti-warpage layer 500 in the non-display area NDA.

According to this embodiment, as the shock-absorbing layer 400_1 covers the upper surface of the anti-warpage layer 500, the contact area between the shock-absorbing layer 400_1 and the anti-warpage layer 500 increases so that the shock-absorbing layer 400_1 and the anti-warpage layer 500 can be more reliably coupled with each other.

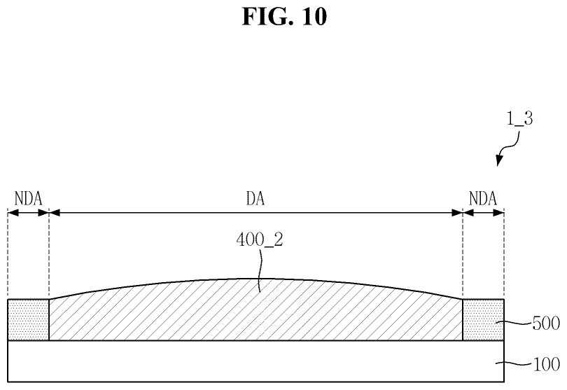

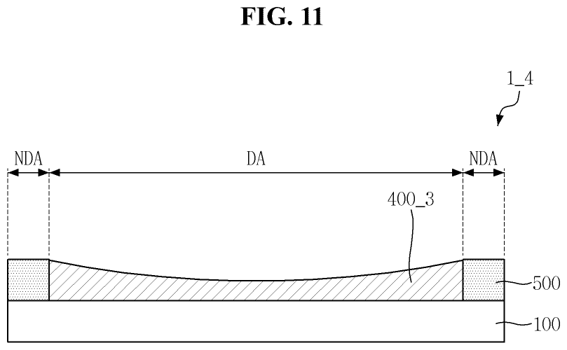

FIGS. 10 and 11 are schematic cross-sectional views of a display device according to yet an embodiment of the disclosure.

The surface shapes of the shock-absorbing layers 400_2 and 400_3 of display devices 1_3 and 1_4 according to the embodiments of FIGS. 10 and 11 may be different from the shape of the embodiment of FIG. 5 which has a substantially flat shape. As shown in FIG. 10, the surface shape of the shock-absorbing layer 400_2 may have a curved line shape that is convex in the thickness direction of the display panel 100. As shown in FIG. 11, the surface shape of the shock-absorbing layer 400_3 may have a concave curved line shape in the thickness direction of the display panel 100. As such, even in case that the surface shapes of the shock-absorbing layers 400_2 and 400_3 may not be substantially flat, it may be still possible to protect the display panel 100 from shock applied to the device.

According to these embodiments, the surfaces of the shock-absorbing layers 400_2 and 400_3 may have a convex or concave shape, and thus they may work as lenses capable of adjusting the angle of light.

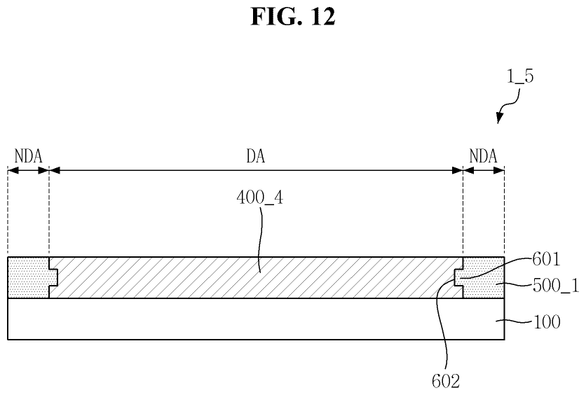

FIG. 12 is a schematic cross-sectional view of a display device according to yet an embodiment of the disclosure.

Unlike the embodiment of FIG. 6 in which the second side surface 404 of the shock-absorbing layer and the inner side surface 503 of the anti-warpage layer may be in surface contact with each other in a straight line in a direction perpendicular to the upper surface 102 of the display panel, they may be coupled with each other by separate coupling means 601 and 602 in a display device 1_5 according to the embodiment of FIG. 12.

The embodiment of FIG. 12 may be different from the embodiment of FIG. 6 in that the former further includes coupling means 601 and 602 for coupling a shock-absorbing layer 400_4 with an anti-warpage layer 500_1.

Specifically, the coupling means 601 and 602 may include a coupling groove 602 disposed in the shock-absorbing layer 400_4, and a coupling protrusion 601 disposed in the anti-warpage layer 500_1 and inserted into the coupling groove 602. It should be understood, however, that the embodiments of the disclosure are not limited thereto. The coupling protrusion 601 may be disposed in the shock-absorbing layer 400_4 and the coupling groove 602 may be disposed in the anti-warpage layer 500_1.

The coupling groove 602 and the coupling protrusion 601 may be molded in advance in the shock-absorbing layer 400_4 and the anti-warpage layer 500_1, respectively, and then fit together. For example, the film-type shock-absorbing layer 400_4 having the coupling groove 602 may be inserted into the inner space of the anti-warpage layer 500_1 such that the coupling protrusion 601 of the anti-warpage layer 500_1 may be inserted into the coupling groove 602 of the film-type shock-absorbing layer 400_4.

It should be understood, however, that the embodiments of the disclosure are not limited thereto. The anti-warpage layer 500_1 having the coupling protrusion 601 may be disposed on the display panel 100, and the inner space of the anti-warpage layer 500_1, which has a rectangular frame shape with an empty space inside, may be filled with a coating liquid for forming the shock-absorbing layer.

According to this embodiment, as the coupling protrusion 601 may be accommodated in the coupling groove 602, the coupling strength between the shock-absorbing layer 400_4 and the anti-warpage layer 500_1 can be improved. Accordingly, it may be possible to firmly support them to prevent the shock-absorbing layer 400_4 and the anti-warpage layer 500_1 from being displaced in case that shock occurs due to external force.

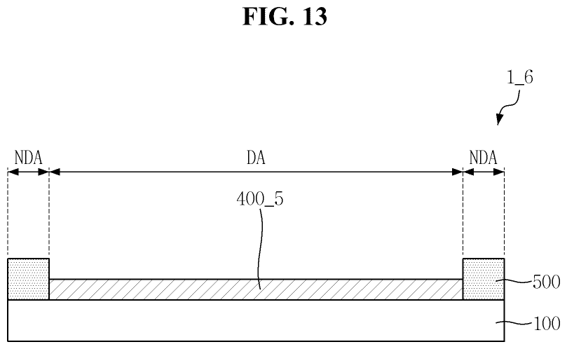

FIG. 13 is a schematic cross-sectional view of a display device according to yet an embodiment of the disclosure.

The embodiment of FIG. 13 may be different from the embodiment of FIG. 6 in that there may be a level difference between the upper surface of a shock-absorbing layer 400_5 and the upper surface of an anti-warpage layer 500 in a display device 1_6.

Specifically, as shown in FIG. 13, the height from the lower surface to the upper surface of the shock-absorbing layer 400_5 may be smaller than the height from the lower surface to the upper surface of the anti-warpage layer 500. It should be understood, however, that the embodiments of the disclosure are not limited thereto. The upper surface of the shock-absorbing layer 400_5 may be higher than the upper surface of the anti-warpage layer 500.

According to this embodiment, the height of the shock-absorbing layer 400_5 may be smaller than the height of the anti-warpage layer 500 so that the material cost for fabricating the shock-absorbing layer 400_5 can be reduced.

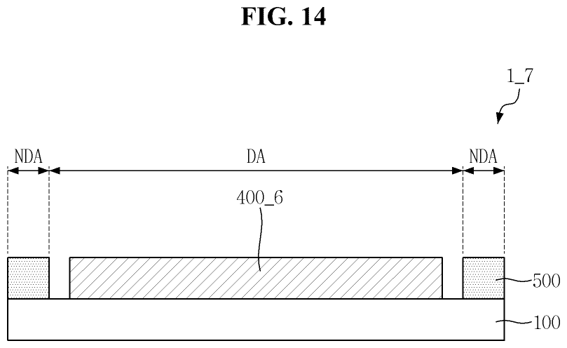

FIG. 14 is a schematic cross-sectional view of a display device according to yet an embodiment of the disclosure.

The embodiment of FIG. 14 may be different from the embodiment of FIG. 6 in that a shock-absorbing layer 400_6 may not be in contact with an anti-warpage layer 500 in a display device 1_7.

Specifically, the shock-absorbing layer 400_6 may have a smaller size than the inner space of the anti-warpage layer 500 having a frame shape with an empty space inside and may be accommodated inside the anti-warpage layer 500. Referring to the schematic cross-sectional view of FIG. 14, the side surface of the shock-absorbing layer 400_6 may be spaced apart from the inner side surface of the anti-warpage layer 500 with a gap, which is the distance therebetween.

According to this embodiment, the shock-absorbing layer 400_6 has a smaller area than the inner space of the anti-warpage layer 500 so that the material cost for fabricating the shock-absorbing layer 400_6 can be reduced.

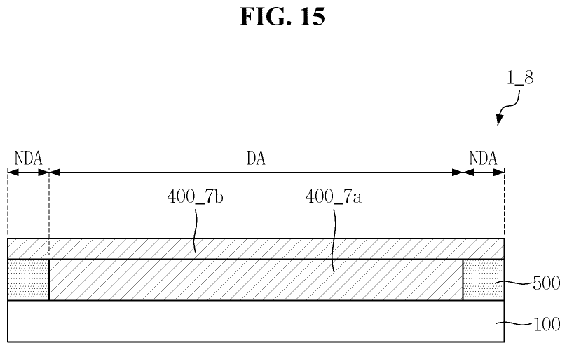

FIG. 15 is a schematic cross-sectional view of a display device according to yet an embodiment of the disclosure.

The embodiment of FIG. 15 may be different from the embodiment of FIG. 6 in that a display device 1_8 has a two-layer structure of first and second shock-absorbing layers 400_7a and 400_7b.

Specifically, as shown in FIG. 15, a first shock-absorbing layer 400_7a may be disposed inside an anti-warpage layer 500 disposed in the display area DA, and a second shock-absorbing layer 400_7b may be disposed to cover the upper surface of the anti-warpage layer 500 in the display area DA and the non-display area NDA.

According to this embodiment, as the second shock-absorbing layer 400_7b covers the upper surface of the anti-warpage layer 500, the side surfaces of the first and second shock-absorbing layer 400_7a may be in contact with the side surfaces of the anti-warpage layer 500, and the upper surface of the anti-warpage layer 500 may be in contact with the second shock-absorbing layer 400_7b, and thus the contact area of the anti-warpage layer 500 can be increased. Accordingly, the first and second shock-absorbing layers 400_7a and 400_7b and the anti-warpage layer 500 can be more reliably coupled with each other.

According to this embodiment, the first shock-absorbing layer 400_7a, which has the same height as the anti-warpage layer 500, may be disposed and then the second shock-absorbing layer 400_7b may be disposed on the substantially flat first shock-absorbing layer 400_7a, thereby improving convenience of the fabrication process.

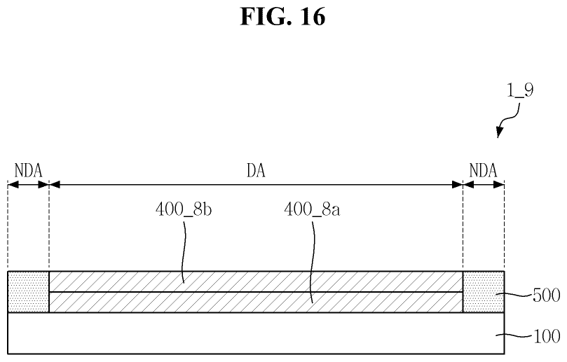

FIG. 16 is a schematic cross-sectional view of a display device according to yet an embodiment of the disclosure.

Referring to FIG. 16, in a display device 1_9 according to this embodiment, a first shock-absorbing layer 400_8a may be disposed inside an anti-warpage layer 500 disposed in the display area, a second shock-absorbing layer 400_8b may be disposed immediately on the first shock-absorbing layer 400_8a, and accordingly both the first shock-absorbing layer 400_8a and the second shock-absorbing layer 400_8b may be accommodated inside the anti-warpage layer 500.

In the examples shown in FIGS. 15 and 16, the first and second shock-absorbing layers 400_7a, 400_7b, 400_8a and 400_8b may be made of different materials or a same material, and may have different strengths. The first shock-absorbing layers 400_7a and 400_8a disposed on the upper surface of the display panel 100 may be soft layers with lower strength than the second shock-absorbing layers 400_7b and 400_8b, but the disclosure is not limited thereto.

According to this embodiment, as shown in FIGS. 15 and 16, since the first and second shock-absorbing layers 400_7a, 400_7b, 400_8a and 400_8b have a two-layer structure, the layers may have different functions selectively. For example, the second shock-absorbing layers 400_7b and 400_8b may have higher strength than the first shock-absorbing layers 400_7a and 400_8a. The second shock-absorbing layers 400_7b and 400_8b may have lower strength than the first shock-absorbing layers 400_7a and 400_8a.

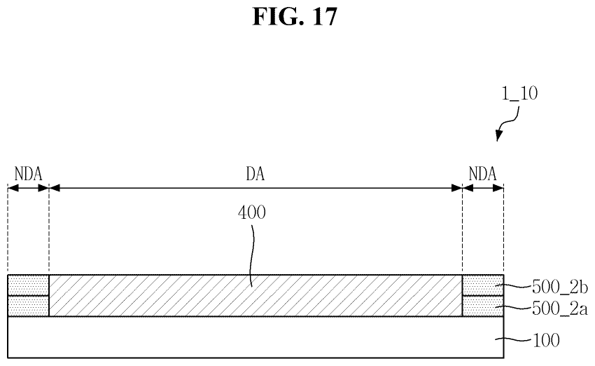

FIG. 17 is a schematic cross-sectional view of a display device according to yet an embodiment of the disclosure.

While the anti-warpage layer 500 may be a single layer and may be disposed in the non-display area NDA in FIG. 6, a display device 1_10 according to the embodiment of FIG. 17 may have a two-layer structure of a first anti-warpage layer 500_2a and a second anti-warpage layer 500_2b.

The first and second anti-warpage layers 500_2a and 500_2b may be made of metals with the same coefficient of thermal expansion (CTE), or may be made of different metals. As an example, the first anti-warpage layer 500_2a may use a metal with a low CTE, and the second anti-warpage layer 500_2b may use a metal with a high CTE, but the disclosure is not limited thereto.

According to this embodiment, if the first anti-warpage layer 500_2a uses a metal with a low CTE while the second anti-warpage layer 500_2b uses a metal with a high CTE, for example, during the reliability evaluation with increasing temperature, in case that a curl occurs in a direction, i.e., in case that a curl occurs upward of the display panel 100, the curl may be induced in the opposite direction, i.e., downward of the display panel 100, thereby suppressing a curl in the final device.

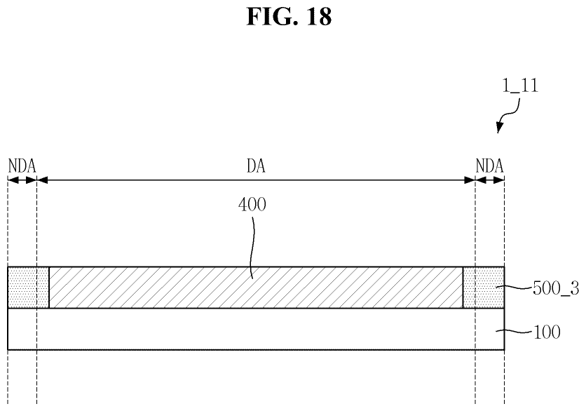

FIGS. 18 to 23 illustrate modifications in terms of the positional relationships between the inner side surface of the anti-warpage layer and the non-display area and the positional relationships between the outer side surface of the anti-warpage layer and the non-display area.

FIG. 18 is a schematic cross-sectional view of a display device according to yet an embodiment of the disclosure.

In the above embodiment of FIG. 6, the inner side surface of the anti-warpage layer 500 may be aligned with the boundary between the display area DA and the non-display area NDA of the display panel 100, but the disclosure is not limited thereto. In a display device 1_11 according to this embodiment, the inner side surface of an anti-warpage layer 500_3 may be disposed inside the display area DA as shown in FIG. 18.

According to this embodiment, since the anti-warpage layer 500_3 may be disposed over a wide area from the non-display area NDA to a part of the display area DA, it can press the display panel 100 with strong force over the wide area so that it may be possible to suppress warpage of the device.

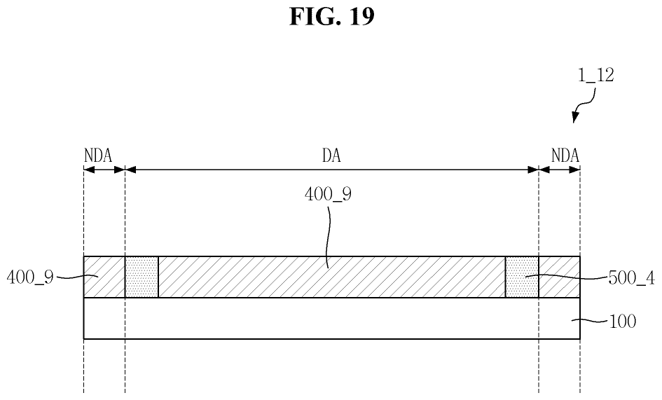

FIG. 19 is a schematic cross-sectional view of a display device according to yet an embodiment of the disclosure.

In a display device 1_12 according to the embodiment of FIG. 19, an anti-warpage layer 500_4 may be entirely disposed inside the display area DA. In this instance, a shock-absorbing layer 400_9 may be additionally disposed on the outer side of the anti-warpage layer 500_4, but the disclosure is not limited thereto.

Specifically, the inner side surface of the anti-warpage layer 500_4 may be disposed inside the display area DA, and the outer side surface of the anti-warpage layer 500_4 may be disposed at the boundary between the display area DA and the non-display area NDA.

According to this embodiment, since the anti-warpage layer 500_4 may be disposed in the central area of the display area DA compared to the embodiment of FIG. 18, especially in case that warpage occurs in the center of the display panel 100, the anti-warpage layer 500_4 disposed close to the center of the display panel 100 can press the display panel 100 in the central area, thereby suppressing warpage in the device.

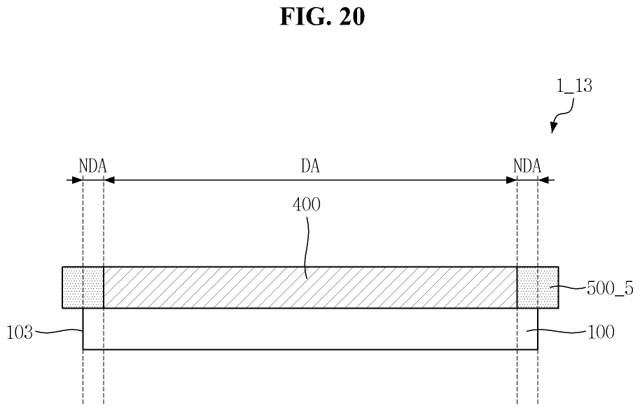

FIG. 20 is a schematic cross-sectional view of a display device according to yet an embodiment of the disclosure.

In a display device 1_13 according to the embodiment of FIG. 20, the inner side surface of the anti-warpage layer 500_5 may be disposed at the boundary between the display area DA and the non-display area NDA, and the anti-warpage layer 500_5 may protrude outward from the side surface 103 of the display panel.

According to this embodiment, since the anti-warpage layer 500_5 may be disposed in the outer perimeter of the display panel 100 compared to the embodiment of FIG. 18, especially in case that warpage occurs from the outer perimeter of the display panel 100, the anti-warpage layer 500_4 disposed in the outer perimeter of the display panel 100 can press the display panel 100 in the outer perimeter, thereby suppressing warpage in the device.

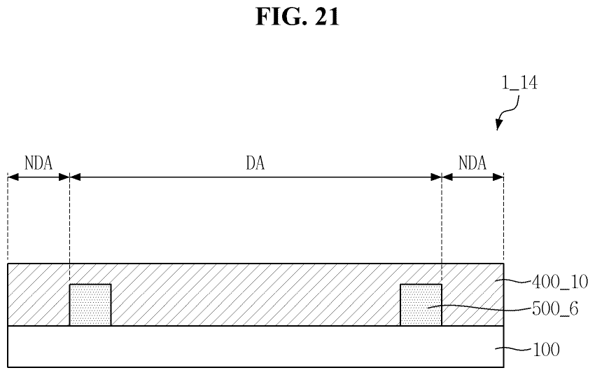

Incidentally, in the above embodiment of FIG. 6, the anti-warpage layer may be disposed at the periphery of the shock-absorbing layer and the inner side surface of the anti-warpage layer may be aligned with the boundary between the display area and the non-display area of the display panel. In contrast, according to the embodiments of FIGS. 21 to 23, the anti-warpage layer may be embedded in the shock-absorbing layer.

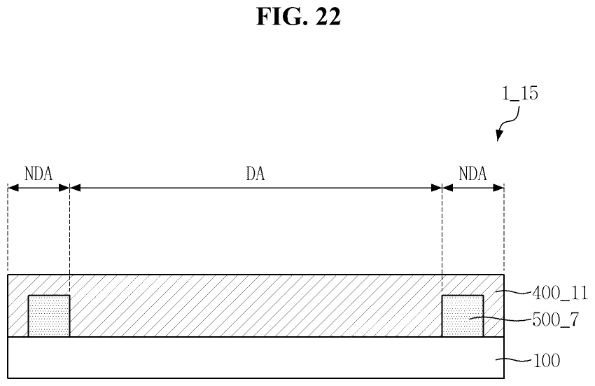

FIGS. 21 and 22 are schematic cross-sectional views of display devices according to other embodiments of the disclosure.

The shock-absorbing layers 400_10 and 400_11 may cover the upper surface, the inner side surface and the outer side surface of the anti-warpage layers 500_6 and 500_7. In a display device 1_14 according to the embodiment of FIG. 21, an anti-warpage layer 500_6 may be disposed inside the display area DA. In a display device 1_15 according to the embodiment of FIG. 22, the inner side surface of an anti-warpage layer 500_7 may be disposed at the boundary between the display area DA and the non-display area NDA.

According to the embodiments of the disclosure, the anti-warpage layers 500_6 and 500_7 may be embedded inside the shock-absorbing layers 400_10 and 400_11 so that they may not be exposed to the outside. Therefore, during the fabrication process, the anti-warpage layers 500_6 and 500_7 may be disposed and then a coating liquid for forming a shock-absorbing layer may be applied only once, and thus the fabrication process can be simplified.

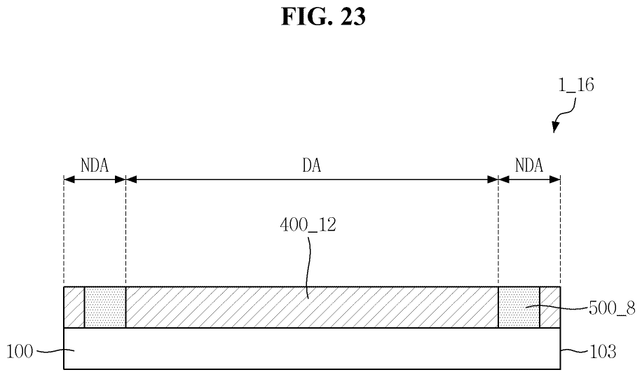

FIG. 23 is a schematic cross-sectional view of a display device according to yet an embodiment of the disclosure.

In a display device 1_16 according to the embodiment of FIG. 23, an anti-warpage layer 500_8 may be embedded in a shock-absorbing layer 400_12 such that the upper surface of the anti-warpage layer 500_8 may be exposed and both the inner and outer surfaces of the anti-warpage layer 500_8 may be in contact with the shock-absorbing layer 400_12. The inner side surface of the anti-warpage layer 500_8 may be disposed at the boundary between the display area DA and the non-display area NDA, and the side surface of the shock-absorbing layer 400_12 may be aligned with the side surface 103 of the display panel.

According to this embodiment, the anti-warpage layer 500_8 has a small size so that it may be disposed in a part of the non-display area, thereby saving the material cost for fabricating the anti-warpage layer 500_8.

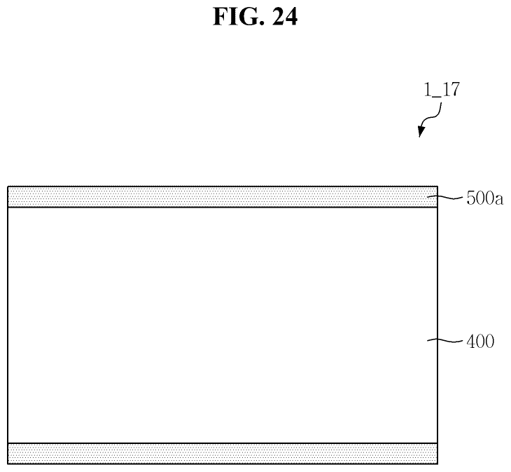

It should be noted that although the anti-warpage layer 500 in the shape of a rectangular frame may be disposed at the periphery of the shock-absorbing layer 400 according to the above-described embodiment of FIG. 6, it may be arranged in a variety of shapes as shown in FIGS. 24 to 29 when viewed from the top.

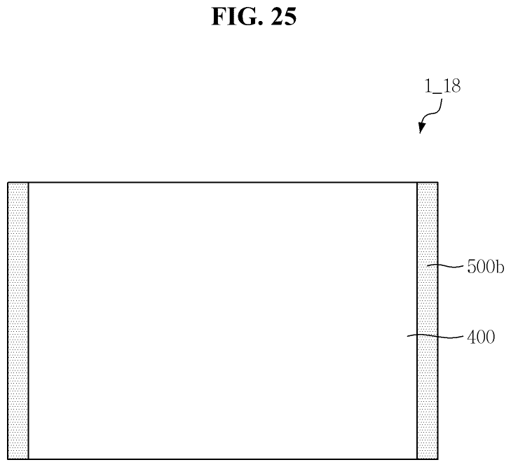

FIGS. 24 and 25 are schematic cross-sectional views of display devices according to other embodiments of the disclosure.

In a rectangular display device 1_17 according to the embodiment of FIG. 24, an anti-warpage layer 500a may be disposed only on the longer sides facing each other. In a display device 1_18 according to the embodiment of FIG. 25, an anti-warpage layer 500b may be disposed only on the shorter sides facing each other.

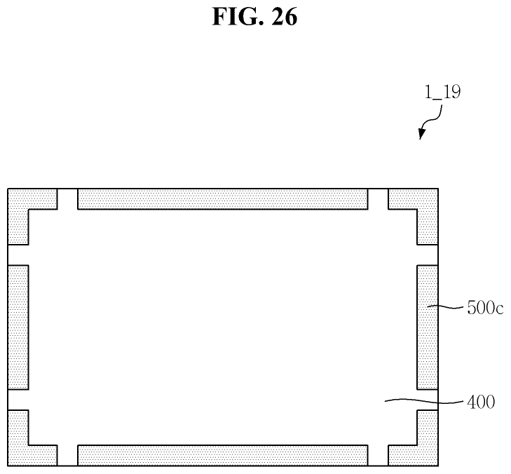

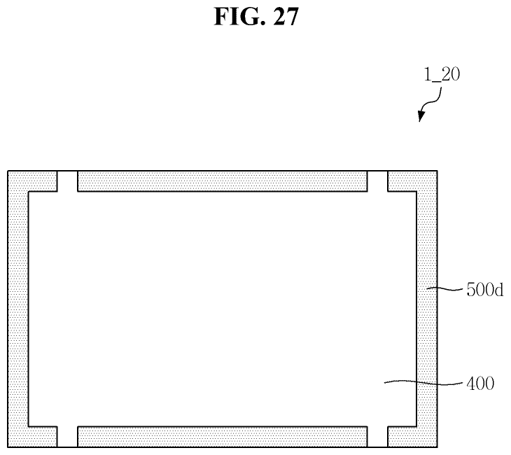

FIGS. 26 and 27 are schematic cross-sectional views of display devices according to other embodiments of the disclosure.

According to the embodiments of the disclosure, anti-warpage layers 500c and 500d of display devices 1_19 and 1_20 have a rectangular shape, and the anti-warpage layers may be disposed on all sides including a pair of longer sides and a pair of shorter sides, with discontinuous sections or slits. For example, the anti-warpage layer 500c may have discontinuous sections on all sides as shown in FIG. 26, or the anti-warpage layer 500d may have discontinuous sections only on the longer sides as shown in FIG. 27.

According to the embodiments, the anti-warpage layers 500c and 500d may be discontinuously disposed in some or all sections of the display panel 100. This allows the anti-warpage layers 500c and 500d to be disposed discontinuously only in certain sections where warpage frequently occurs depending on different device characteristics, to block warpage. By doing so, it may be possible to save material costs for the anti-warpage layer 500c and 500d.

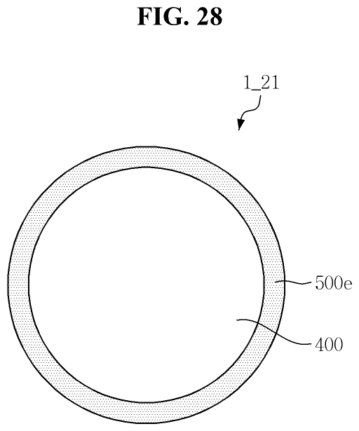

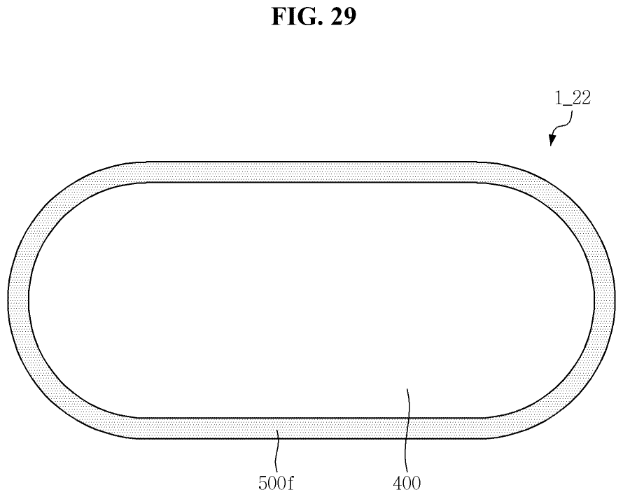

FIGS. 28 and 29 are schematic cross-sectional views of display devices according to other embodiments of the disclosure.

In a circular display device 1_21 according to the embodiment of FIG. 28, an anti-warpage layer 500e may also be circular with an opening in the center conforming to the shape of the display device 1_21. In an oval display device 1_22 according to the embodiment of FIG. 29, an anti-warpage layer 500f may also be oval with an opening in the center conforming to the shape of the display device 1_21.

According to the embodiments of the disclosure, the anti-warpage layers 500e and 500f can be disposed in the shapes conforming to the shapes of the display devices 1_21 and 1_22 so that the anti-warpage layers 500e and 500f can be applied to devices having a circular shape, such as a watch to suppress warpage.

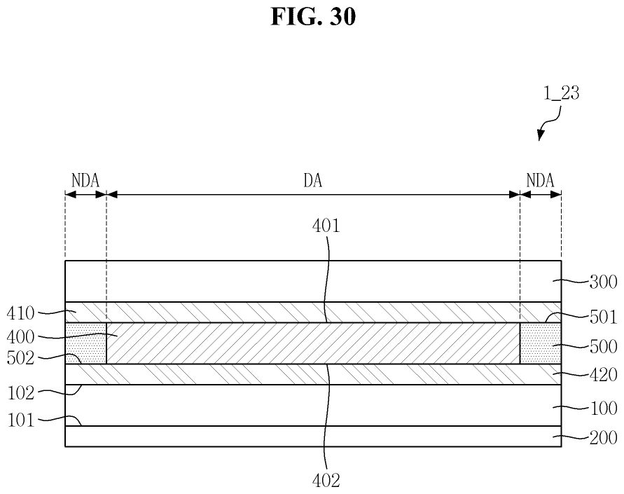

FIG. 30 is a schematic cross-sectional view of a display device according to yet an embodiment of the disclosure.

FIG. 30 shows an example in which a first soft layer 410 and a second soft layer 420 may be further added to the display device 1_1 of FIG. 8.

The embodiment of FIG. 30 may be different from the embodiment of FIG. 8 in that a display device 1_23 further includes a first soft layer 410 disposed on the upper side of the shock-absorbing layer 400 and a second soft layer 420 disposed on the lower side of the shock-absorbing layer 400.

The first soft layer 410 may be disposed between the shock-absorbing layer 400 and the polarizing member 300 in the thickness direction of the display panel 100.

Specifically, the lower surface of the first soft layer 410 may be in contact with the upper surface 401 of the shock-absorbing layer 400 and the upper surface 501 of the anti-warpage layer 500, and the upper surface of the first soft layer 410 may be in contact with the polarizing member 300.

The lower surface of the first soft layer 410 may be in contact (e.g., direct contact) with the upper surface 401 of the shock-absorbing layer and the upper surface 501 of the anti-warpage layer, or a separate layer may be disposed therebetween. The upper surface of the first soft layer 410 may be in contact (e.g., direct contact) with the polarizing member 300, or a separate layer may be disposed therebetween.

The first soft layer 410 may relieve stress and strain on the display panel 100 in case that the display panel 100 is folded or in case that an external shock is applied to the display panel 100.

The second soft layer 420 may be disposed between the shock-absorbing layer 400 and the display panel 100 in the thickness direction of the display panel 100.

Specifically, the upper surface of the second soft layer 420 may be in contact with the lower surface 402 of the shock-absorbing layer and the lower surface 502 of the anti-warpage layer 500, and the lower surface of the second soft layer 420 may be in contact with the upper surface 102 of the display panel.

The upper surface of the second soft layer 420 may be in contact (e.g., direct contact) with the lower surface 402 of the shock-absorbing layer and the lower surface 502 of the anti-warpage layer, or a separate layer may be disposed therebetween. The lower surface of the second soft layer 420 may be in contact (e.g., direct contact) with the upper surface 102 of the display panel, or a separate layer may be disposed therebetween.

The second soft layer 420 may relieve stress and strain on the display panel 100 in case that the display panel 100 is folded or in case that an external shock is applied to the display panel 100.

The second soft layer 420 may work as a buffer material between the display panel 100 and the shock-absorbing layer 400. Specifically, in case that the display panel 100 is a glass substrate, by disposing the second soft layer 420 between the display panel made of a hard material and the shock-absorbing layer 400, it may be possible to relieve stress on the display panel 100 in case that it is bent, compared to in case that they are in contact (e.g., direct contact) with each other. For example, the second soft layer 420 can reduce stress.

The first soft layer 410 and the second soft layer 420 may have a lower strength than the shock-absorbing layer 400, and the modulus of the first soft layer 410 and the second soft layer 420 may range from about 1 kPa to about 1 GPa, preferably in a range of about 0.01 MPa to about 1 MPa. It should be understood, however, that the disclosure is not limited thereto.

As the first soft layer 410 and the second soft layer 420 have a lower strength than the shock-absorbing layer, they can give flexibility to the harder shock-absorbing layer so that stress on the display panel 100 can be reduced. At least one of the first soft layer 410 and the second soft layer 420 may include an adhesive. For example, if the first soft layer 410 includes an adhesive, the first soft layer 410 can attach the polarizing member 300 to the shock-absorbing layer 400 without a separate adhesive layer, and if the second soft layer 420 includes an adhesive, the display panel 100 can be attached to the shock-absorbing layer 400 without a separate adhesive layer. As such, the elements can be coupled without a separate adhesive layer so that the thickness of the device can be reduced.

The first soft layer 410 and the second soft layer 420 may have a thickness in a range of about 5 to about 200 μm, preferably in a range of about 25 to about 100 μm. It should be understood, however, that the disclosure is not limited thereto.

If the thicknesses of the first soft layer 410 and the second soft layer 420 are about 5 μm or more, the thickness of the device can be reduced. If the thicknesses may be less than about 200 μm and they include an adhesive as described above, the first soft layer 410 can firmly support the polarizing member 300 on the shock-absorbing layer 400, and the second soft layer 420 can firmly support the shock-absorbing layer 400 on the display panel 100.

The first soft layer 410 and the second soft layer 420 may be made of a same material, may have the same modulus, may have the same thickness, and may include an adhesive. It should be understood, however, that the embodiments of the disclosure are not limited thereto. They may be made of different materials, have different moduli, or have different thicknesses, and one of the first soft layer 410 and the second soft layer 420 may include an adhesive.

According to this embodiment, the first soft layer 410 and the second soft layer 420 may be disposed to reduce the overall hardness of the device, thereby reducing stress on the display panel 100.

In case that the first soft layer 410 and the second soft layer 420 include an adhesive, the positions of the polarizing member 300 and the display panel 100 can be supported and the coupling strength can be improved.

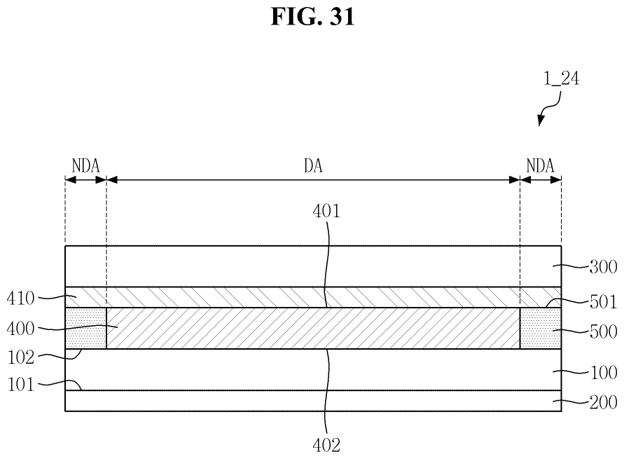

FIG. 31 is a schematic cross-sectional view of a display device according to yet an embodiment of the disclosure.

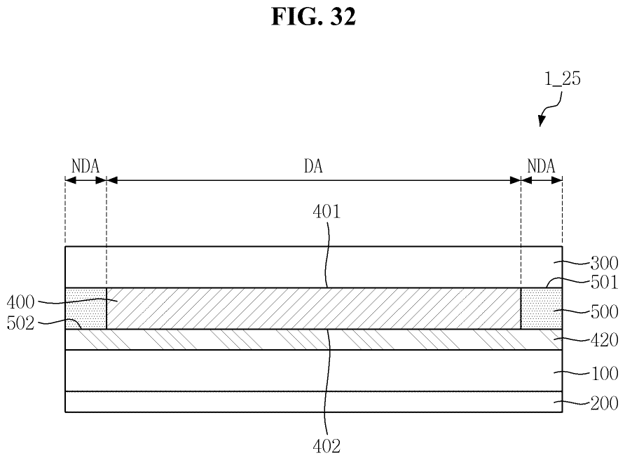

While the first soft layer 410 and the second soft layer 420 may be disposed on the upper and lower surfaces of the shock-absorbing layer 400 in the display device 1_23 of FIG. 30, respectively, a first soft layer 410 may be disposed only on the upper surface of a shock-absorbing layer 400 in a display device 1_24 according to the embodiment of FIG. 31, or a second soft layer 420 may be disposed only on the lower surface of a shock-absorbing layer 400 in a display device 1_25 according to the embodiment of FIG. 32.

Specifically, referring to FIG. 31, the upper surface 401 of the shock-absorbing layer and the upper surface 501 of the anti-warpage layer may be in contact with the first soft layer 410, and the lower surface 402 of the shock-absorbing layer and the lower surface 502 of the anti-warpage layer may be in contact with the upper surface 102 of the display panel.

Referring to FIG. 32, the upper surface 401 of the shock-absorbing layer and the upper surface 501 of the anti-warpage layer may be in contact with a polarizing member 300, and the lower surface 402 of the shock-absorbing layer and the lower surface 502 of the anti-warpage layer may be in contact with the second soft layer 420.

According to the embodiments of FIGS. 31 and 32, it may be possible to selectively locate only one of the first soft layer 410 and the second soft layer 420, and thus the fabrication cost can be saved compared to the embodiment of FIG. 30 including both the first soft layer 410 and the second soft layer 420.

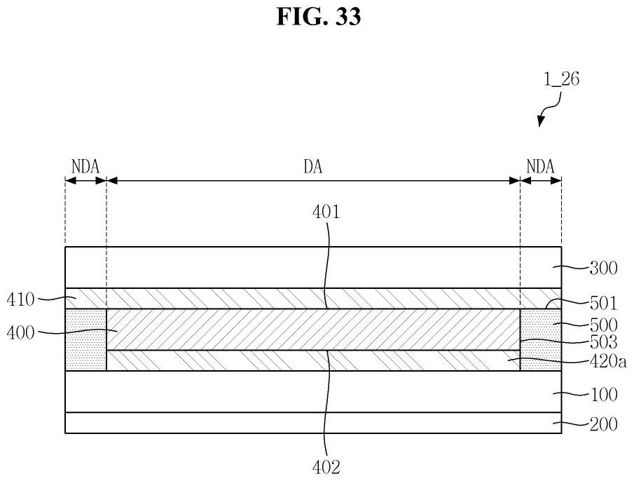

FIG. 33 is a schematic cross-sectional view of a display device according to yet an embodiment of the disclosure.

While both of the lower surface 402 of the shock-absorbing layer and the lower surface 502 of the anti-warpage layer 500 may be in contact with the second soft layer 420 in the example shown in FIG. 30, in a display device 1_26 according to the embodiment of FIG. 33, the lower surface 402 of the shock-absorbing layer may be in contact with the upper surface of the second soft layer 420a, and a part of an inner side surface 503 of the anti-warpage layer may be in contact with a side surface of the second soft layer 420.

Specifically, while the anti-warpage layer 500 may be disposed at the periphery of the shock-absorbing layer 400 in the example shown in FIG. 30, the anti-warpage layer 500 may be disposed at the periphery of the shock-absorbing layer 400 and at the periphery of the second soft layer 420a in the example shown in FIG. 33.

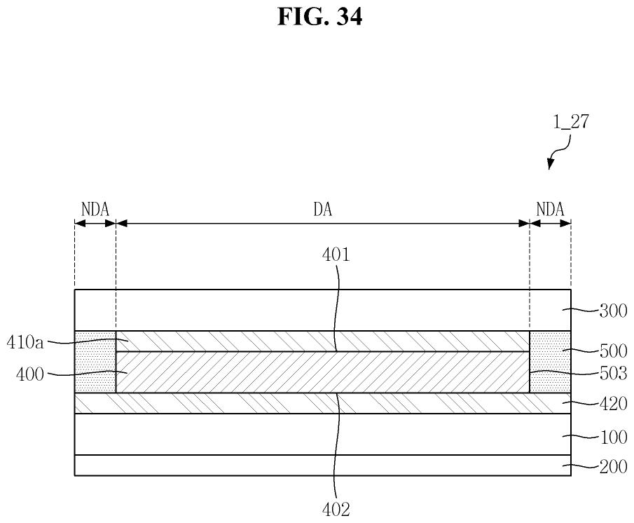

FIG. 34 is a schematic cross-sectional view of a display device according to yet an embodiment of the disclosure.

While both of the upper surface 401 of the shock-absorbing layer and the upper surface 501 of the anti-warpage layer 500 may be in contact with the first soft layer 410 in the example shown in FIG. 30, in a display device 1_27 according to the embodiment of FIG. 34, the upper surface 401 of the shock-absorbing layer may be in contact with the lower surface of a first soft layer 410a, and a part of an inner side surface of the anti-warpage layer 500 may be in contact with a side surface of the first soft layer 410a.

Specifically, while the anti-warpage layer 500 may be disposed at the periphery of the shock-absorbing layer 400 in the example shown in FIG. 30, the anti-warpage layer 500 may be disposed at the periphery of the shock-absorbing layer 400 and at the periphery of the first soft layer 410a in the example shown in FIG. 34.

According to the embodiments of FIGS. 33 and 34, the anti-warpage layer 500 may be disposed at the periphery of the shock-absorbing layer 400 and the first soft layer 410a or disposed at the periphery of the shock-absorbing layer 400 and the second soft layer 420a so that the positions of the shock-absorbing layer 400 as well as the first soft layer 410a or the second soft layer 420a can be supported together, and it may be possible to prevent displacement between the shock-absorbing layer 400 and the first soft layer 410a or the second soft layer 420a by external shock.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A display device comprising:
a display panel comprising a display area and a non-display area around the display area;
a shock-absorbing layer disposed on the display panel and disposed in the display area; and
an anti-warpage layer disposed on the display panel, the anti-warpage layer disposed in the non-display area and disposed at least partially along an edge area of the shock-absorbing layer.

2. The display device of claim 1, wherein the shock-absorbing layer has an upper surface being substantially flat.

3. The display device of claim 2, wherein the anti-warpage layer has an upper surface being substantially flat.

4. The display device of claim 3, wherein the upper surface of the shock-absorbing layer and the upper surface of the anti-warpage layer are coplanar with each other.

5. The display device of claim 1, wherein the shock-absorbing layer is a transparent resin layer, has a same shape as the display area of the display panel, and overlaps the display area of the display panel.

6. The display device of claim 3, wherein
the shock-absorbing layer comprises a lower surface facing an upper surface of the display panel, an upper surface opposite to the lower surface of the shock-absorbing layer, and a side surface disposed in a peripheral direction between the lower surface of the shock-absorbing layer and the upper surface of the shock-absorbing layer, and
the side surface of the shock-absorbing layer is in contact with the anti-warpage layer in the peripheral direction.

7. The display device of claim 6, further comprising:
a soft layer disposed on at least one of the upper surface and the lower surface of the shock-absorbing layer,
wherein the soft layer has a lower strength than the shock-absorbing layer.

8. The display device of claim 7, wherein the soft layer comprises:
a first soft layer in contact with the upper surface of the shock-absorbing layer, and
a second soft layer in contact with the lower surface of the shock-absorbing layer.

9. The display device of claim 8, wherein
the second soft layer is disposed between the lower surface of the shock-absorbing layer and the upper surface of the display panel, and
the second soft layer has a lower strength than the first soft layer.

10. The display device of claim 8, further comprising:
a polarizing member in contact with the upper surface of the shock-absorbing layer; and
a cover panel disposed on a lower surface of the display panel, wherein the lower surface of the display panel is opposite to the upper surface of the display panel.

11. The display device of claim 1, wherein
the anti-warpage layer has a rectangular frame, a circular shape, or oval shape comprising an empty space inside, and
the shock-absorbing layer is accommodated in the empty space of the anti-warpage layer.

12. The display device of claim 4, wherein
the anti-warpage layer has a same shape as the non-display area of the display panel, and
the anti-warpage layer overlaps the non-display area.

13. The display device of claim 1, wherein the anti-warpage layer comprises a resin or a metal having a greater strength than the shock-absorbing layer.

14. The display device of claim 13, wherein the anti-warpage layer comprises at least one material selected from the group consisting of aluminum (Al), carbon fiber-reinforced plastic (CFRP), and stainless steel (SUS304).

15. The display device of claim 6, wherein
the anti-warpage layer comprises an inner side surface in contact with the side surface of the shock-absorbing layer in a peripheral direction,
the anti-warpage layer further comprises an outer side surface disposed at an outermost position on an opposite side to the inner side surface of the anti-warpage layer, and
an outer side surface of the display panel at the outermost position and the outer side surface of the anti-warpage layer are disposed in a same plane that extends in a vertical direction perpendicular to the upper surface of the display panel.

16. The display device of claim 15, further comprising:
a soft layer disposed on at least one of the upper surface and the lower surface of the shock-absorbing layer, the soft layer having a lower strength than that of the shock-absorbing layer, wherein
the anti-warpage layer comprises an upper surface disposed above the inner side surface and the outer side surface of the anti-warpage layer,
the anti-warpage layer further comprises a lower surface opposite to the upper surface of the anti-warpage layer, and
at least one of the inner side surface, the upper surface and the lower surface of the anti-warpage layer is in contact with the soft layer.

17. A display device comprising:
a display panel comprising a first area and a second area disposed adjacent to the first area;
a resin layer disposed on the first area of the display panel and having a first strength; and
a frame layer disposed on the second area of the display panel and having a second strength greater than the first strength.

18. The display device of claim 17, wherein the second strength is in a range of about 5 to about 50 times the first strength.

19. The display device of claim 17, wherein
the frame layer comprises a metal frame with an empty space inside, and
the metal frame has a width in a range of about 1 mm to about 10 mm.

20. The display device of claim 17, wherein the resin layer and the frame layer are at least partially in contact with each other.
